(19) United States
(12) Patent Application Publication
(10) Pub. No.: US 2025/0087646 A1
(43) Pub. Date: Mar. 13, 2025

(54) SEMICONDUCTOR PACKAGE INCLUDING BACKSIDE POWER DELIVERY NETWORK LAYER

(71) Applicant: SAMSUNG ELECTRONICS CO., LTD., Suwon-si (KR)

(72) Inventors: Hyunsoo CHUNG, Suwon-si (KR); Kwang-Soo KIM, Suwon-si (KR); Jaesic LEE, Suwon-si (KR)

(73) Assignee: SAMSUNG ELECTRONICS CO., LTD., Suwon-si (KR)

(21) Appl. No.: 18/606,888

(22) Filed: Mar. 15, 2024

(30) Foreign Application Priority Data
Sep. 12, 2023 (KR) 10-2023-0120849

(51) Int. Cl. H01L 25/10; H01L 23/00; H01L 23/31; H01L 23/48; H01L 23/498; H01L 23/528; H01L 23/538

(52) U.S. Cl. CPC H01L 25/105; H01L 23/3128; H01L 23/481; H01L 23/49811; H01L 23/5286; H01L 23/5383; H01L 24/08; H01L 24/16; H01L 24/32; H01L 24/48; H01L 24/73; H01L 2224/08225; H01L 2224/16227; H01L 2224/32225; H01L 2224/48227; H01L 2224/73204; H01L 2224/73265

(57) ABSTRACT

A semiconductor package includes a first redistribution substrate, a first semiconductor chip on the first redistribution substrate, a first mold layer at least partially covering the first redistribution substrate and the first semiconductor chip, a plurality of first conductive pillars at least partially penetrating the first mold layer and contacting the first redistribution substrate, a second redistribution substrate on the first mold layer, a second semiconductor chip on the second redistribution substrate, a second mold layer at least partially covering the second redistribution substrate and the second semiconductor chip, a plurality of second conductive pillars at least partially penetrating the second mold layer and contacting the second redistribution substrate, and a third redistribution substrate on the second mold layer. The first semiconductor chip includes a first through via. The second semiconductor chip includes a backside power delivery network layer.

### CROSS-REFERENCE TO RELATED APPLICATIONS

This application claims benefit of priority under 35 U.S.C § 119 to Korean Patent Application No. 10-2023-0120849, filed on Sep. 12, 2023, in the Korean Intellectual Property Office, the disclosure of which is incorporated by reference herein in its entirety.

### BACKGROUND

### 1. Field

The present disclosure relate generally to a semiconductor package, and more particularly, to a fan-out wafer level semiconductor package (FOWLP) including a backside power delivery network (BSPDN) layer.

### 2. Description of Related Art

A semiconductor package may be provided to implement an integrated circuit chip for use in electronic products. Typically, a semiconductor package may configured such that a semiconductor chip may be mounted on a printed circuit board (PCB) and bonding wires and/or bumps may be used to electrically connect (couple) the semiconductor chip to the PCB. There exists a need for further improvements in semiconductor packaging technology, as increasing demand for electronic products may be constrained by reliability and/or durability of semiconductor packages. Improvements are presented herein. These improvements may also be applicable to other semiconductor technologies and the standards that employ these technologies.

### SUMMARY

One or more example embodiments of the present disclosure provide a semiconductor package with potentially increased power efficiency and potentially improved thermal radiation performance, when compared with related semiconductor packages.

According to an aspect of the present disclosure, a semiconductor package includes a first redistribution substrate, a first semiconductor chip on the first redistribution substrate, a first mold layer at least partially covering the first redistribution substrate and the first semiconductor chip, a plurality of first conductive pillars at least partially penetrating the first mold layer and contacting the first redistribution substrate, a second redistribution substrate on the first mold layer, a second semiconductor chip on the second redistribution substrate, a second mold layer at least partially covering the second redistribution substrate and the second semiconductor chip, a plurality of second conductive pillars at least partially penetrating the second mold layer and contacting the second redistribution substrate, and a third redistribution substrate on the second mold layer. The first semiconductor chip includes a first through via. The second semiconductor chip includes a backside power delivery network layer.

According to an aspect of the present disclosure, a semiconductor package includes a first sub-package and a second sub-package on the first sub-package. The first sub-package includes a first redistribution substrate, a first semiconductor chip on the first redistribution substrate, a first mold layer at least partially covering the first redistribution substrate and the first semiconductor chip, a plurality of first conductive pillars at least partially penetrating the first mold layer and contacting the first redistribution substrate, a second redistribution substrate on the first mold layer, a second semiconductor chip on the second redistribution substrate, a second mold layer at least partially covering the second redistribution substrate and the second semiconductor chip, a plurality of second conductive pillars at least partially penetrating the second mold layer and contacting the second redistribution substrate, and a third redistribution substrate on the second mold layer. The first semiconductor chip includes a first through via. The second semiconductor chip includes a backside power delivery network layer. The first semiconductor chip has a first width in a first direction. The second semiconductor chip has a second width in the first direction. The second width is greater than the first width.

According to an aspect of the present disclosure, a semiconductor package includes a first redistribution substrate, a first semiconductor chip on the first redistribution substrate, a first mold layer at least partially covering the first redistribution substrate and the first semiconductor chip, a plurality of first conductive pillars at least partially penetrating the first mold layer and contacting the first redistribution substrate, a second redistribution substrate on the first mold layer, a second semiconductor chip on the second redistribution substrate, a second mold layer at least partially covering the second redistribution substrate and the second semiconductor chip, a plurality of second conductive pillars at least partially penetrating the second mold layer and contacting the second redistribution substrate, and a third redistribution substrate on the second mold layer. The first semiconductor chip includes a first through via. A bottom surface of the first semiconductor chip is in contact with the first redistribution substrate. The second semiconductor chip includes a backside power delivery network layer. The first semiconductor chip has a first width in a first direction. The second semiconductor chip has a second width in the first direction. The second width is greater than the first width.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 illustrates a cross-sectional view showing a semiconductor package, according to some embodiments;

FIG. 2 illustrates an enlarged view showing section P1 of FIG. 1, according to some embodiments;

FIG. 3 illustrates a cross-sectional view showing a semiconductor package, according to some embodiments;

FIGS. 4A to 4E illustrate cross-sectional views showing a method of fabricating a second semiconductor chip of FIG. 1, according to some embodiments;

FIGS. 5A to 5F illustrate cross-sectional views showing a method of fabricating a semiconductor package of FIG. 1, according to some embodiments; and

FIG. 6 illustrates a cross-sectional view showing a semiconductor package, according to some embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element. Further, when an element or layer is referred to as “surrounding” another element or layer, the element or layer may surround at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “Si₃N₄”, “SiO₂”, “SiOₓN_{y}”, and the like may refer to a material made of elements included in each of the terms and is not a chemical formula representing a stoichiometric relationship.

Hereinafter, various embodiments of the present disclosure are described with reference to the accompanying drawings.

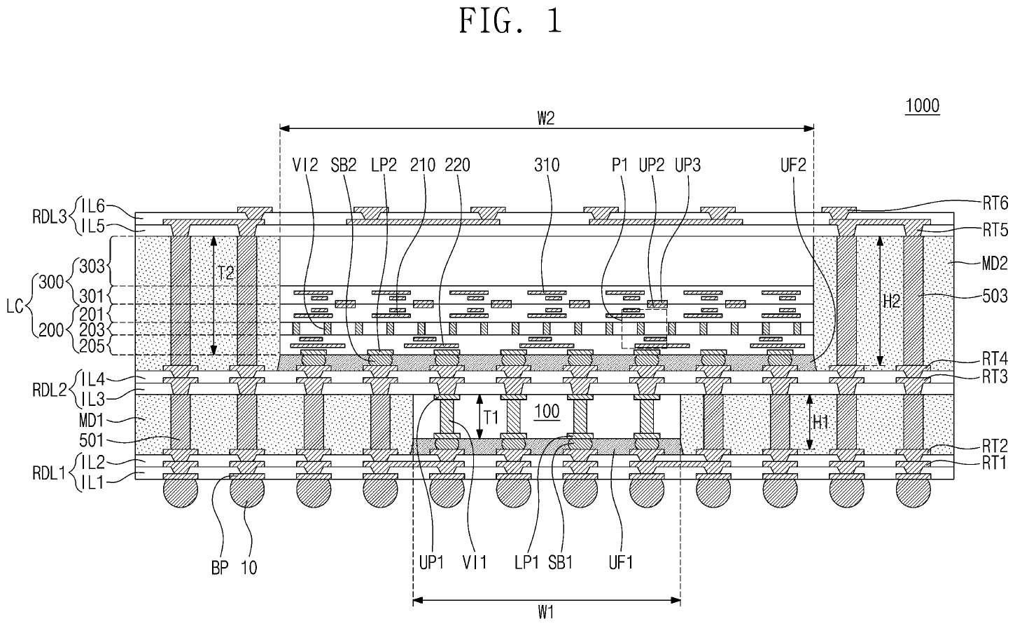

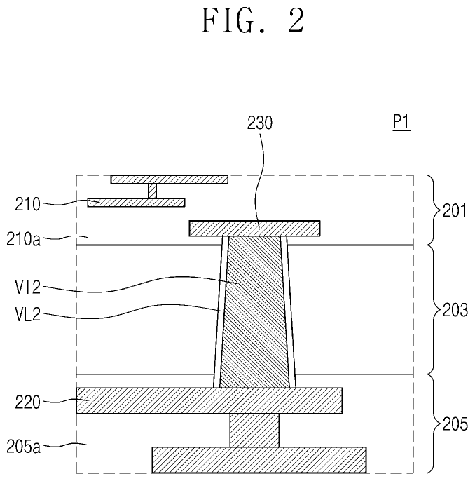

FIG. 1 illustrates a cross-sectional view showing a semiconductor package, according to some embodiments. FIG. 2 illustrates an enlarged view showing section P1 of FIG. 1, according to some embodiments.

Referring to FIG. 1, a semiconductor package 1000 may be shaped similar to a chip-last type fan-out wafer level package (FOWLP). The semiconductor package 1000 may include a first redistribution substrate RDL1 and a first semiconductor chip 100 mounted thereon. The first redistribution substrate RDL1 and the first semiconductor chip 100 may be covered with a first mold layer MD1. A second redistribution substrate RDL2 may be disposed on the first mold layer MD1. First conductive pillars 501 may penetrate the first mold layer MD1 to electrically connect (e.g., couple) the first redistribution substrate RDL1 to the second redistribution substrate RDL2. A second semiconductor chip LC may be mounted on the second redistribution substrate RDL2. The second redistribution substrate RDL2 and the second semiconductor chip LC may be covered with a second mold layer MD2. A third redistribution substrate RDL3 may be disposed on the second mold layer MD2. Second conductive pillars 503 may penetrate the second mold layer MD2 to electrically connect the second redistribution substrate RDL2 to the third redistribution substrate RDL3.

The first redistribution substrate RDL1 may include a first redistribution dielectric layer IL1 and a second redistribution dielectric layer IL2 that may be sequentially stacked. However, the present disclosure is not limited thereto, and the first redistribution substrate RDL1 may be formed of three (3) or more redistribution dielectric layers. The first and second redistribution dielectric layers IL1 and IL2 may include a photo-imageable dielectric (PID) layer. Alternatively or additionally, the first and second redistribution dielectric layers IL1 and IL2 may include an Ajinomoto build-up film (ABF). A first redistribution pattern RT1 may be interposed between the first redistribution dielectric layer IL1 and the second redistribution dielectric layer IL2. A second redistribution pattern RT2 may be interposed between the second redistribution dielectric layer IL2 and the first mold layer MD1.

Lower bonding pads BP may be disposed on a bottom surface of the first redistribution dielectric layer IL1. The lower bonding pads BP may be in contact with the first redistribution pattern RT1. The first and second redistribution patterns RT1 and RT2 and the lower bonding pads BP may include, but not be limited to, at least one copper (Cu), aluminum (Al), tungsten (W), nickel (Ni), gold (Au), tin (Sn), and titanium (Ti). In an embodiment, a barrier/seed layer may cover sidewalls and lower surfaces of the first and second redistribution patterns RT1 and RT2. The barrier/seed layer may include a barrier layer and a seed layer that may be sequentially stacked. The barrier layer may include a metal nitride layer. The seed layer may include a same metal as a metal of the first and second redistribution patterns RT1 and RT2. External connection members 10 may be bonded to the lower bonding pads BP. The external connection members 10 may include, but not be limited to, at least one of solder balls, conductive bumps, and conductive pillars. The external connection members 10 may include, but not be limited to, at least one of tin (Sn), lead (Pb), silver (Ag), copper (Cu), aluminum (Al), gold (Au), and nickel (Ni).

The first semiconductor chip 100 may include input/output (I/O) terminals. The first semiconductor chip 100 may be configured to perform as an interface circuit between the second semiconductor chip LC and an external controller. For example, the first semiconductor chip 100 may transfer data, which may be released (outputted) by the second semiconductor chip LC, through the I/O terminals to the external controller. In an embodiment, the first semiconductor chip 100 may include a first substrate, an interlayer dielectric layer, and an internal line.

The first semiconductor chip 100 may include a first through via VI1. The first through via VI1 may penetrate the first substrate of the first semiconductor chip 100. In an embodiment, a first through dielectric layer may be interposed between the first through via VI1 and the first substrate. The first through via VI1 may include metal, such as, but not limited to, copper (Cu), aluminum (Al), tungsten (W), and the like. The first semiconductor chip 100 may be electrically connected through the first through via VI1 to the first redistribution substrate RDL1 and the second redistribution substrate RDL2.

First upper conductive pads UP1 may be disposed on a top surface of the first semiconductor chip 100, and first lower conductive pads LP1 may be disposed on a bottom surface of the first semiconductor chip 100. The first upper conductive pads UP1 and the first lower conductive pads LP1 may be respectively connected to the first through vias VI1.

First inner connection members SB1 may be used to flip-chip bond the first semiconductor chip 100 to the first redistribution substrate RDL1. The first inner connection members SB1 may electrically connect the first lower conductive pads LP1 of the first semiconductor chip 100 to the second redistribution pattern RT2 corresponding thereto. The first inner connection members SB1 may include, but not be limited to, at least one of solder balls, conductive bumps, and conductive pillars. The first inner connection members SB1 may include, but not be limited to, at least one of tin (Sn), lead (Pb), silver (Ag), aluminum (Al), gold (Au), and nickel (Ni).

A first underfill UF1 may be interposed between the first semiconductor chip 100 and the first redistribution substrate RDL1. The first underfill UF1 may be formed by dispensing and/or curing processes. The first underfill UF1 may include an epoxy resin, and may protect the first inner connection members SB1.

The first mold layer MD1 may cover the first semiconductor chip 100 and a top surface of the first redistribution substrate RDL1. The first mold layer MD1 may include a dielectric resin, such as, but not limited to, an epoxy molding compound (EMC). The first mold layer MD1 may further include fillers, and the fillers may be dispersed in the dielectric resin. The fillers may include, for example, silicon oxide (SiO₂). However, the present disclosure is not limited thereto, and the fillers may include other elements.

The second redistribution substrate RDL2 may be disposed on the first semiconductor chip 100 and the first mold layer MD1. The second redistribution substrate RDL2 may include a third redistribution dielectric layer IL3 and a fourth redistribution dielectric layer IL4 that may be sequentially stacked. However, the present disclosure is not limited thereto, and the second redistribution substrate RDL2 may be formed of three (3) or more redistribution dielectric layers. The third and fourth redistribution dielectric layers IL3 and IL4 may include a PID layer. Alternatively or additionally, the third and fourth redistribution dielectric layers IL3 and IL4 may include an ABF. A third redistribution pattern RT3 may be interposed between the third redistribution dielectric layer IL3 and the fourth redistribution dielectric layer IL4. A fourth redistribution pattern RT4 may be interposed between the fourth redistribution dielectric layer IL4 and the second mold layer MD2.

The first conductive pillars 501 may be spaced apart from the first semiconductor chip 100. In an embodiment, when viewed in a plan view, the first conductive pillars 501 may be disposed to surround the first semiconductor chip 100. The first conductive pillars 501 may be respectively electrically connected to the second redistribution pattern RT2 and the third redistribution pattern RT3. The top surfaces of the first conductive pillars 501 may be coplanar with the top surface of the first mold layer MD1. The first conductive pillars 501 may include, for example, but not be limited to, copper (Cu).

The second semiconductor chip LC may be and/or may include a semiconductor package including a plurality of semiconductor dies having the same or different types. In an embodiment, the second semiconductor chip LC may have a structure in which a first semiconductor die 200 and a second semiconductor die 300 may be bonded to each other. For example, the second semiconductor chip LC may have a three-dimensional (3D) structure including a logic chip. As another example, the first semiconductor die 200 and the second semiconductor die 300 may have a chiplet structure in which the first and second semiconductor dies 200 and 300 may be bonded in a wafer-on-wafer manner.

Second inner connection members SB2 may be used to flip-chip bond the second semiconductor chip LC to the second redistribution substrate RDL2. The second inner connection members SB2 may electrically connect second lower conductive pads LP2 of the second semiconductor chip LC to the fourth redistribution pattern RT4 corresponding thereto. The second inner connection members SB2 may include, but not be limited to, at least one of solder balls, conductive bumps, and conductive pillars. The second inner connection members SB2 may include, but not be limited to, at least one of tin (Sn), lead (Pb), silver (Ag), aluminum (Al), gold (Au), and nickel (Ni).

A second underfill UF2 may be interposed between the second semiconductor chip LC and the second redistribution substrate RDL2. The second underfill UF2 may be formed by dispensing and/or curing processes. The second underfill UF2 may include, but not be limited to, an epoxy resin, and may protect the second inner connection members SB2.

The first semiconductor die 200 may be and/or may include, for example, a logic chip. The first semiconductor die 200 may include a backside power delivery network layer 205, a second substrate 203 on the backside power delivery network layer 205, and a frontside wiring layer 201 on the second substrate 203. Referring to FIG. 2, the backside power delivery network layer 205 may include a first interlayer dielectric layer 205a and a first power line 220. In an embodiment, the second substrate 203 may be provided thereon with transistors each including source/drain regions and a gate electrode. Lower metal layers may be additionally disposed below the first interlayer dielectric layer 205a. The frontside wiring layer 201 may include a second interlayer dielectric layer 201a, a signal line 210, and a second power line 230. A width of the first power line 220 may be greater than a width of the signal line 210.

The second substrate 203 may be and/or may include a wafer-level semiconductor substrate formed of a semiconductor, such as, but not limited to, silicon (Si). For example, the second substrate 203 may be and/or may include a semiconductor monocrystalline substrate and/or a silicon-on-insulator (SOI) substrate. A second through via VI2 may be provided to penetrate the second substrate 203, a portion of the first interlayer dielectric layer 205a, and a portion of the second interlayer dielectric layer 201a. The second through via VI2 may electrically connect the first power line 220 to the second power line 230. For example, a voltage may be applied from the backside power delivery network layer 205 through the second through via VI2 to the second power line 230 provided in the second interlayer dielectric layer 201a. A second through dielectric layer VL2 may be interposed between the second through via VI2 and the second substrate 203. The second through via VI2 may include metal, such as, but not limited to, aluminum (Al), copper (Cu), tungsten (W), ruthenium (Ru), molybdenum (Mo), and cobalt (Co). The second through dielectric layer VL2 may include a silicon-based dielectric material (e.g., a silicon oxide (SiO₂) layer, a silicon nitride (Si₃N₄) layer, or a silicon oxynitride (SiOₓN_{y}) layer). As the backside power delivery network layer 205 is disposed on the first semiconductor die 200, the semiconductor package 1000 may have increased power efficiency and increased integration, when compared to a related semiconductor package.

The second semiconductor die 300 may be and/or may include a memory chip, such as, but not limited to, a static random-access memory (SRAM). However, the present disclosure is not limited thereto, and the second semiconductor die 300 may be and/or may include other types of memories, such as, but not limited to, dynamic random-access memory (DRAM), NAND flash memory, magneto-resistive random-access memory (MRAM), phase-change random-access memory (PRAM), resistive random-access memory (RRAM or ReRAM), and the like. The second semiconductor die 300 may include a third substrate 303. The third substrate 303 may be and/or may include a wafer-level semiconductor substrate formed of a semiconductor, such as, but not limited to, silicon (Si). For example, the third substrate 303 may be and/or may include a semiconductor monocrystalline substrate or a SOI substrate. The third substrate 303 may be provided on its active surface with integrated circuits including a transistor and an internal line 310. A third interlayer dielectric layer 301 may be disposed to cover the third substrate 303 and the integrated circuits.

The second semiconductor die 300 may be overturned and bonded to the first semiconductor die 200 to allow an active surface of the second semiconductor die 300 to face the first semiconductor die 200. Second upper conductive pads UP2 may be disposed on a top surface of the first semiconductor die 200, and second lower conductive pads LP2 may be disposed on a bottom surface of the first semiconductor die 200. Third upper conductive pads UP3 may be disposed on a top surface of the second semiconductor die 300. The conductive pads LP2, UP2, and UP3 may include metal, such as, but not limited to, at least one of copper (Cu), gold (Au), nickel (Ni), tin (Sn), silver (Ag), tungsten (W), and aluminum (Al). The second upper conductive pads UP2 may be respectively in direct contact with the third upper conductive pads UP3. The second and third upper conductive pads UP2 and UP3 may be formed of a same material. Contacted ones of the second and third conductive pads UP2 and UP3 may be merged into a single unitary body. Thus, no interface may be present between the contacted ones of the second and third upper conductive pads UP2 and UP3. Therefore, the second semiconductor die 300 may operate with a power supplied from the backside power delivery network layer 205 of the first semiconductor die 200.

Alternatively or additionally, the second semiconductor die 300 may be a silicon dummy die including no integrated circuit. When the second semiconductor die 300 is a silicon dummy die, the first semiconductor die 200 may not include the second upper conductive pads UP2, and the second semiconductor die 300 may not include the third upper conductive pads UP3. In such embodiments, the first semiconductor die 200 and the second semiconductor die 300 may be bonded in an oxide bonding manner.

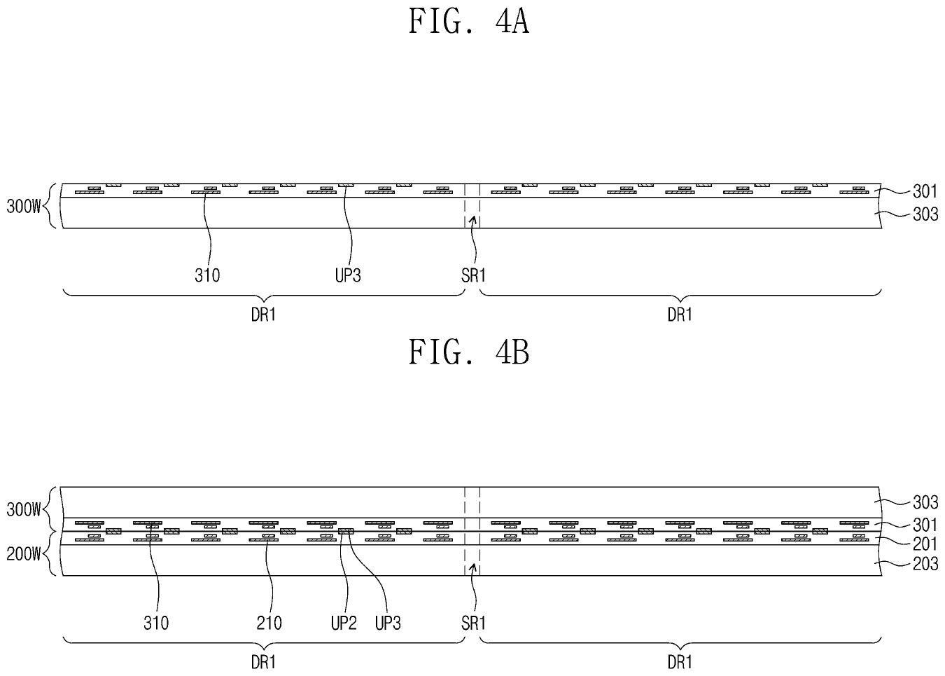

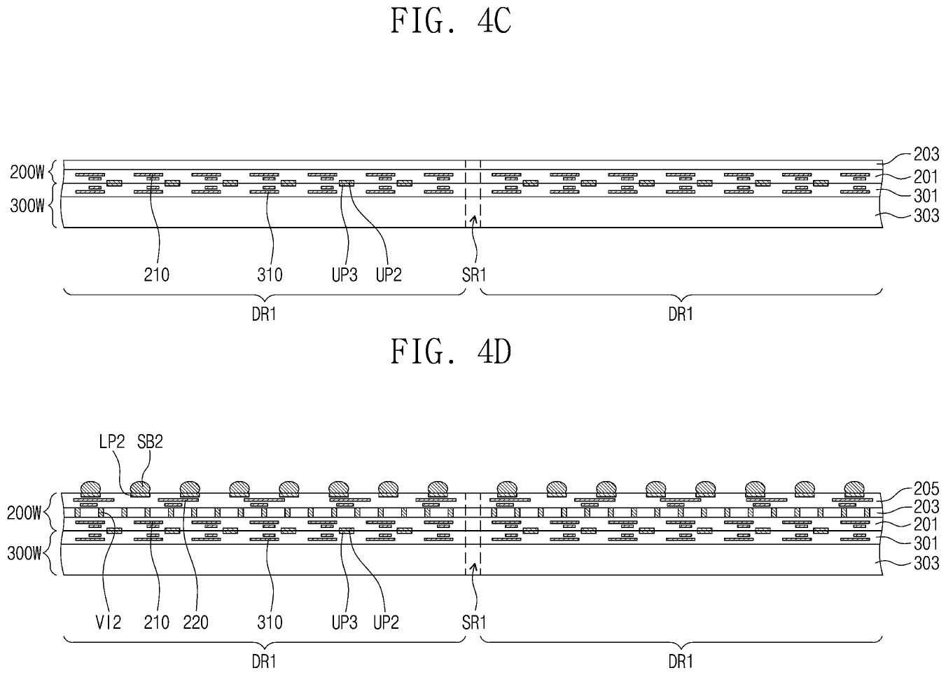

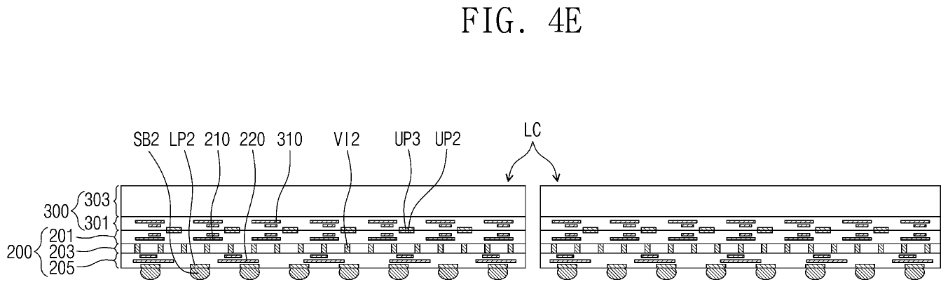

The first semiconductor chip 100 may have a first width W1 in a first direction X, and the second semiconductor chip LC may have a second width W2 in the first direction X. The second width W2 may be greater than the first width W1. As the second semiconductor chip LC, whose width may greater than that of the first semiconductor chip 100 and that includes a logic chip generating a larger amount of heat than that of the first semiconductor chip 100, may be disposed on the second redistribution substrate RDL2 positioned higher than the first semiconductor chip 100, the semiconductor package 1000 may improve in thermal radiation performance, when compared to related semiconductor packages. As the first semiconductor die 200 and the second semiconductor die 300 are bonded in a wafer-on-wafer manner and then undergo a sawing process as described with reference to FIGS. 4A to 4E, the first semiconductor die 200 and the second semiconductor die 300 may be formed to have the same size. The first semiconductor chip 100 may have a first thickness T1 in a second direction Z, and the second semiconductor chip LC may have a second thickness T2 in the second direction Z. The second thickness T2 may be greater than the first thickness T1.

The second mold layer MD2 may cover the second semiconductor chip LC and a top surface of the second redistribution substrate RDL2. The second mold layer MD2 may include a dielectric resin, such as, but not limited to, an EMC. The second mold layer MD2 may further include fillers, and the fillers may be dispersed in the dielectric resin. The fillers may include, for example, silicon oxide (SiO₂). However, the present disclosure is not limited thereto, and the fillers may include other elements.

The third redistribution substrate RDL3 may be disposed on the second semiconductor chip LC and the second mold layer MD2. The third redistribution substrate RDL3 may include a fifth redistribution dielectric layer IL5 and a sixth redistribution dielectric layer IL6 that may be sequentially stacked. However, the present disclosure is not limited thereto, and the third redistribution substrate RDL3 may be formed of three (3) or more redistribution dielectric layers. The fifth and sixth redistribution dielectric layers IL5 and IL6 may include a PID layer. Alternatively or additionally, the fifth and sixth redistribution dielectric layers IL5 and IL6 may include an ABF. A fifth redistribution pattern RT5 may be disposed between the fifth and sixth redistribution dielectric layers IL5 and IL6. A sixth redistribution pattern RT6 may be disposed in the sixth redistribution dielectric layer IL6.

The second conductive pillars 503 may be spaced apart from the second semiconductor chip LC. In an embodiment, when viewed in a plan view, the second conductive pillars 503 may be disposed to surround the second semiconductor chip LC. The second conductive pillars 503 may be respectively electrically connected to the fourth redistribution pattern RT4 and the fifth redistribution pattern RT5. The second conductive pillars 503 may be coplanar with the top surface of the second mold layer MD2. The second conductive pillars 503 may include, for example, but not be limited to, copper (Cu). The first conductive pillars 501 may have a first height H1, and the second conductive pillars 503 may have a second height H2. The second height H2 may be greater than the first height H1.

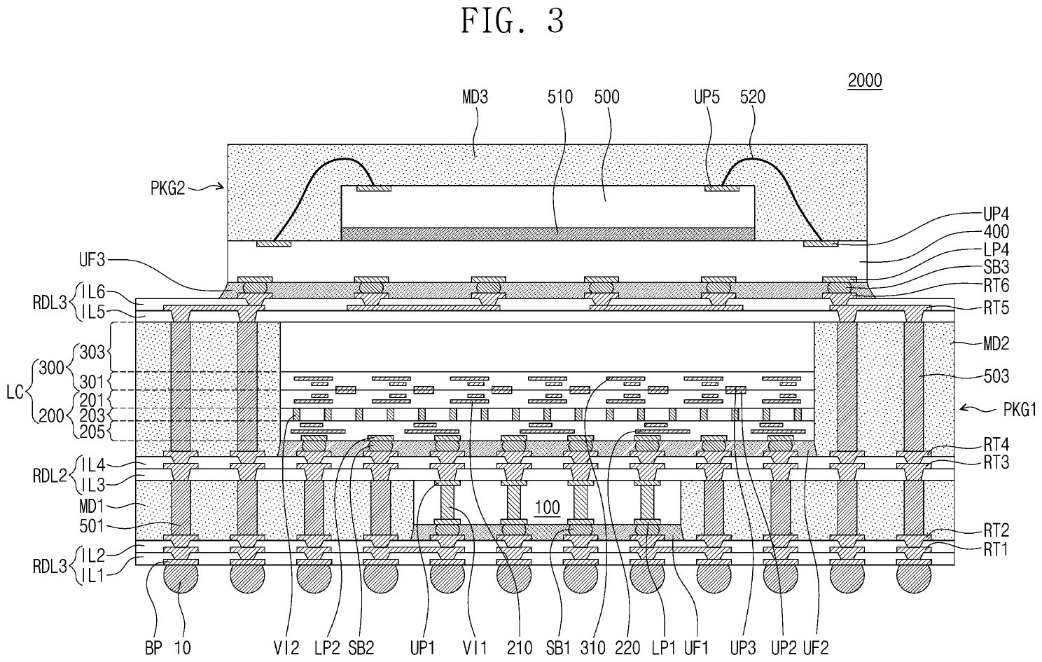

FIG. 3 illustrates a cross-sectional view showing a semiconductor package, according to some embodiments.

Referring to FIG. 3, a semiconductor package 2000 may have a structure in which a second sub-package PKG2 may be mounted on a first sub-package PKG1 that may have the same structure as that of the semiconductor package 1000 described with reference to in FIG. 1. That is, the first sub-package PKG1 of FIG. 3 may include and/or may be similar in many respects to the first sub-package PKG1 described above with reference to FIG. 1, and may include additional features not mentioned above. Consequently, repeated descriptions of the first sub-package PKG1 described above with reference to FIG. 1 may be omitted for the sake of brevity.

The second sub-package PKG2 may include a package substrate 400, a third semiconductor die 500 mounted through a bonding wire 520 on the package substrate 400, and a third mold layer MD3 that may cover the bonding wire 520, the third semiconductor die 500, and the package substrate 400. The bonding wire 520 may electrically connect fourth upper conductive pads UP4 of the package substrate 400 to fifth upper conductive pads UP4 of the third semiconductor die 500. An adhesive layer 510 may be interposed between the package substrate 400 and the third semiconductor die 500.

The second sub-package PKG2 may be mounted through third inner connection members SB3 to the third redistribution substrate RDL3. The third inner connection members SB3 may electrically connect fourth lower conductive pads LP4 of the package substrate 400 to the sixth redistribution pattern RT6 of the third redistribution substrate RDL3. A third underfill UF3 may be interposed between the second sub-package PKG2 and the third redistribution substrate RDL3. The third underfill UF3 may protect the third inner connection members SB3.

However, the present disclosure is not limited thereto, and the second sub-package PKG2 may have a semiconductor package structure including one semiconductor die (or chip) and/or a plurality of semiconductor chips. Other configurations may be substantially similar and/or the same as configurations described with reference to FIGS. 1 and 2.

FIGS. 4A to 4E illustrate cross-sectional views showing a method of fabricating a second semiconductor chip of FIG. 1, according to some embodiments.

Referring to FIG. 4A, a second semiconductor die wafer 300W may be prepared. The second semiconductor die wafer 300W may have a plurality of first chip regions DR1 and a first separation region SR1 between the first chip regions DR1. The first chip regions DR1 of the second semiconductor die wafer 300W may each have a structure substantially similar and/or the same as a structure of the second semiconductor die 300 described with reference to FIG. 1. The first separation region SR1 may be and/or may include a scribe lane region. The second semiconductor die wafer 300W may be and/or may include a third substrate 303. Transistors and an internal line 310 may be formed on the third substrate 303, and a third interlayer dielectric layer 301 may be formed to cover the transistors and the internal line 310. Third upper conductive pads UP3 may be formed on the third interlayer dielectric layer 301.

Referring to FIGS. 2 and 4B, a first semiconductor die wafer 200W may be prepared. A method that may be substantially similar and/or the same as the method described with reference to FIG. 4A may be used to form a second substrate 203, transistors, a signal line 210, a second interlayer dielectric layer 201a, and second upper conductive pads UP2 on the first semiconductor die water 200W. The second semiconductor die wafer 300W of FIG. 4A may be overturned, and a direct bonding process and/or a hybrid copper bonding process may be employed to bond the second semiconductor die wafer 300W to the first semiconductor die wafer 200W. The first semiconductor die wafer 200W and the second semiconductor die wafer 300W may be bonded in a wafer-on-wafer manner. The first and second semiconductor die wafers 200W and 300W may be positioned to allow a frontside wiring layer 201 to contact the third interlayer dielectric layer 301 and to allow the second upper conductive pads UP2 to contact the third upper conductive pads UP3. In an embodiment, a thermal compression process may be performed to directly bond the second semiconductor die wafer 300W to the first semiconductor die wafer 200W.

Referring to FIG. 4C, a structure of FIG. 4B may be overturned, and a grinding process may be performed to remove a portion of the second substrate 203.

Referring to FIGS. 2 and 4D, a back-end-of-line (BEOL) process may be performed to form a second through via VI2, a second through dielectric layer VL2, power lines (e.g., first power line 220 and second power line 230), and a first interlayer dielectric layer 205a on a bottom surface of the first semiconductor die wafer 200W to which the grinding process has been applied. Thus, the first semiconductor die wafer 200W may include a backside power delivery network layer 205, a second substrate 203, and a frontside wiring layer 201. Second lower conductive pads LP2 may be formed on a lower portion of the backside power delivery network layer 205. Second inner connection members SB2 may be bonded to the second lower conductive pads LP2.

Referring to FIG. 4E, a dicing process using a laser may be performed such that the first separation region SR1 may be removed to form a plurality of second semiconductor chips LC. As a result, the second semiconductor chip LC may be formed as shown in FIG. 1. When the dicing process is performed, wafer-on-wafer bonded semiconductor dies 200 and 300 may be formed to have the same size, which may result in an increase in assembly process yield, when compared to related semiconductor packages.

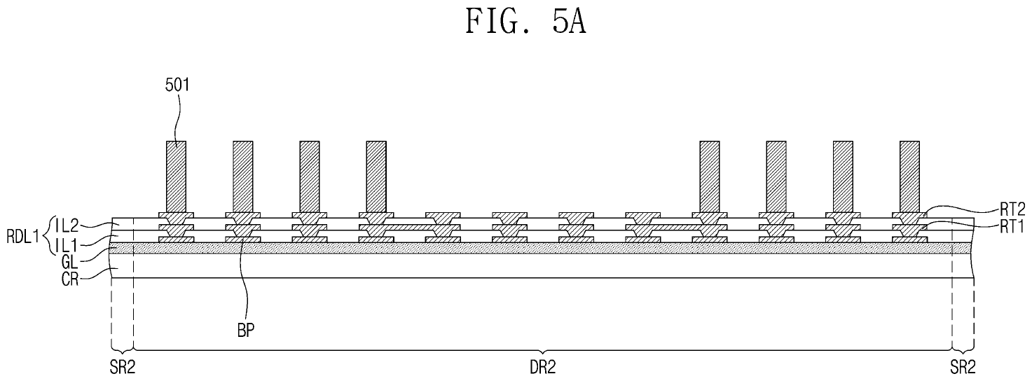

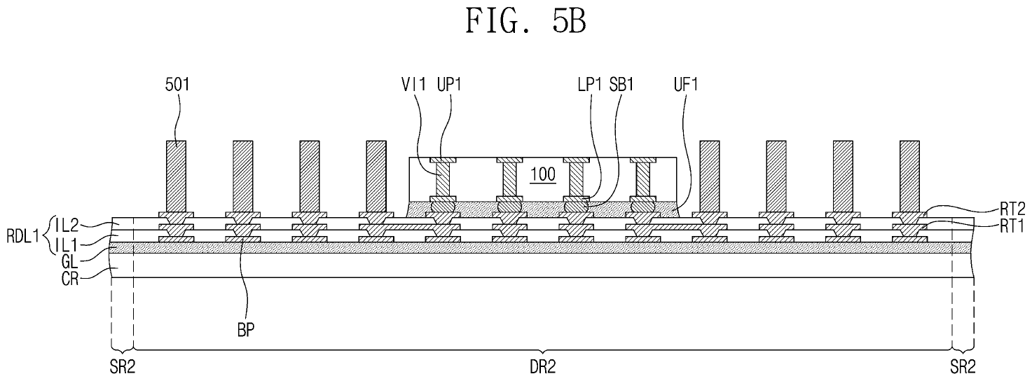

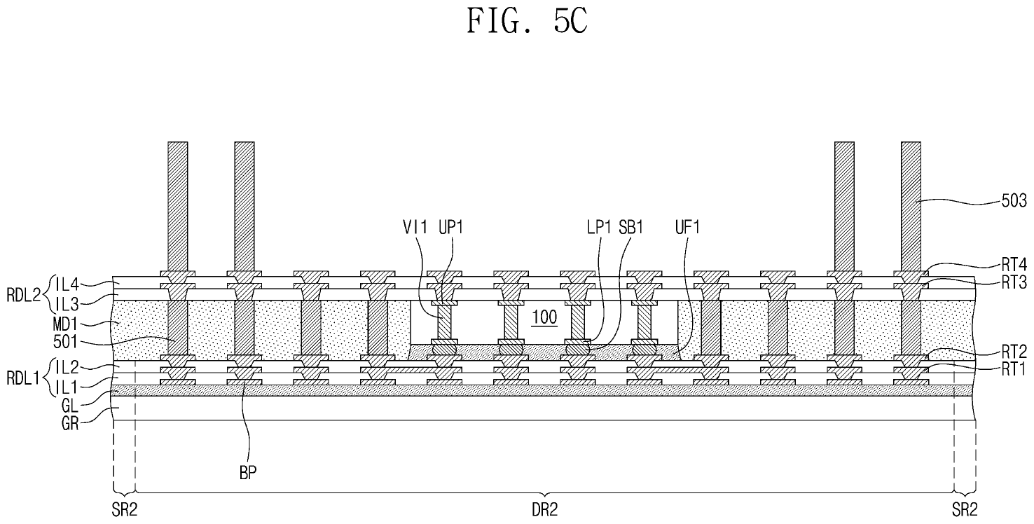

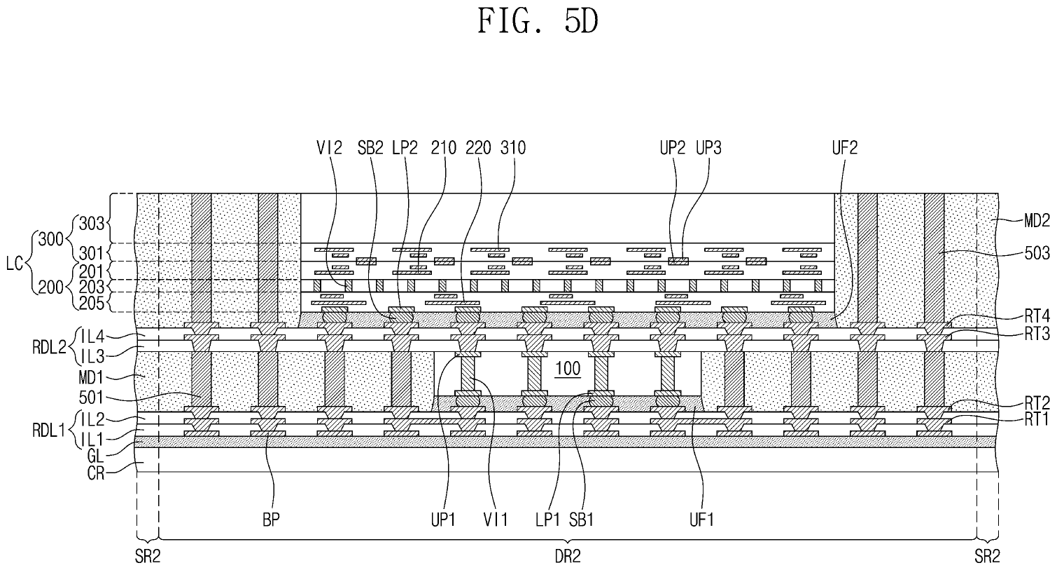

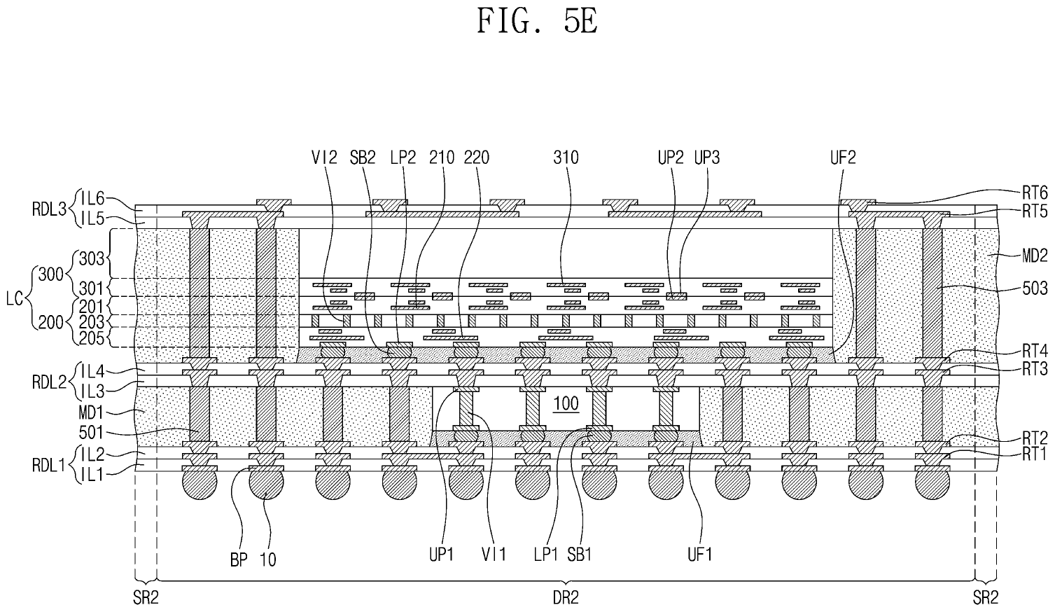

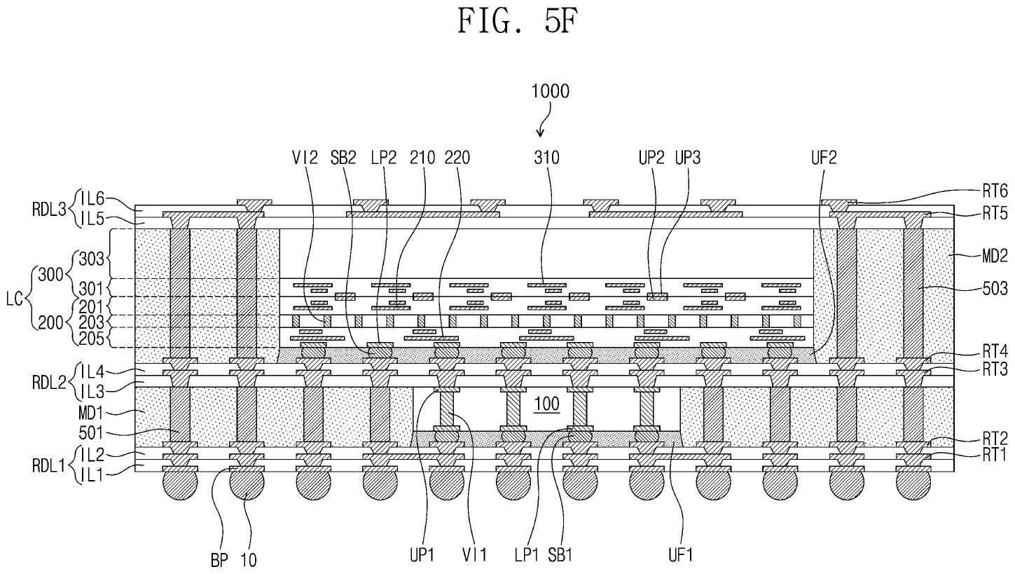

FIGS. 5A to 5F illustrate cross-sectional views showing a method of fabricating a semiconductor package of FIG. 1, according to some embodiments.

Referring to FIG. 5A, a carrier substrate CR may be prepared. A carrier adhesive layer GL may be attached to the carrier substrate CR. The carrier adhesive layer GL may include one or more of an adhesive resin, a thermosetting resin, a thermoplastic resin, and a photo-curable resin. The carrier substrate CR may include a plurality of second separation regions SR2 and a second chip region DR2 between the second separation regions SR2.

A first redistribution substrate RDL1 may be formed on the carrier substrate CR. The first redistribution substrate RDL1 may also include a plurality of second separation regions SR2 and a second chip region DR2 between the second separation regions SR2. A first redistribution dielectric layer IL1 may be formed on the carrier substrate CR. The first redistribution dielectric layer IL1 may be patterned to form via holes. A conductive layer may be formed on the first redistribution dielectric layer IL1 so as to fill the via holes, and the conductive layer may be patterned to form a first redistribution pattern RT1. This procedure may be performed repeatedly to form the first redistribution substrate RDL1 including a second redistribution dielectric layer IL2, a second redistribution pattern RT2, and lower bonding pads BP. First conductive pillars 501 may be formed on the first redistribution substrate RDL1. The first conductive pillars 501 may be adjacent to an edge of the second chip region DR2.

Referring to FIG. 5B, a first semiconductor chip 100 may be prepared. First upper conductive pads UP1 may be formed on a top surface of the first semiconductor chip 100, and first lower conductive pads LP1 may be formed on a bottom surface of the first semiconductor chip 100. A first through via VI1 and a first through dielectric layer may be formed to penetrate a first substrate of the first semiconductor chip 100. First inner connection members SB1 may be used to flip-chip bond the first semiconductor chip 100 to the first redistribution substrate RDL1. The first semiconductor chip 100 may be spaced apart from the first conductive pillars 501. The first semiconductor chip 100 may be formed to have a height that may be less than the height of the first conductive pillars 501. A first underfill UF1 may be formed between the first semiconductor chip 100 and the first redistribution substrate RDL1.

Referring to FIG. 5C, a mold process may be performed to form a first mold layer MD1 that may cover a top surface of the first redistribution substrate RDL1, the first semiconductor chip 100, and the first conductive pillars 501. In an embodiment, a chemical mechanical process (CMP) and/or an etch-back process may be performed to remove at least a portion of the first mold layer MD1 and at least portions of the first conductive pillars 501. This step may expose the top surface of the first semiconductor chip 100, top surfaces of the first conductive pillars 501, and a top surface of the first mold layer MD1. The top surface of the first mold layer MD1 may be coplanar with the top surfaces of the first conductive pillars 501.

A second redistribution substrate RDL2 may be formed on the first semiconductor chip 100 and the first mold layer MD1. A method that may be substantially similar and/or the same as the method described with reference to FIG. 5A may be employed to form a third redistribution dielectric layer IL3, a fourth redistribution dielectric layer IL4, a third redistribution pattern RT3, and a fourth redistribution pattern RT4. The third redistribution pattern RT3 may be in direct contact with the first conductive pillars 501. Second conductive pillars 503 may be formed on the second redistribution substrate RDL2. The second conductive pillars 503 may be adjacent to an edge of the second chip region DR2.

Referring to FIG. 5D, a second semiconductor chip LC may be prepared. The second semiconductor chip LC may be formed by a method that may be substantially similar and/or the same as the method described with reference to FIGS. 4A to 4E. The second semiconductor chip LC may be the same as the second semiconductor chip LC discussed in FIGS. 1 and 2. The second semiconductor chip LC of FIG. 5D may include and/or may be similar in many respects to the second semiconductor chip LC described above with reference to FIGS. 1 and 2, and may include additional features not mentioned above. Consequently, repeated descriptions of the second semiconductor chip LC described above with reference to FIGS. 1 and 2 may be omitted for the sake of brevity.

Second inner connection members SB2 may be used to flip-chip bond the second semiconductor chip LC to the second redistribution substrate RDL2. The second semiconductor chip LC may be spaced apart from the second conductive pillars 503. The second semiconductor chip LC may be formed to have a height that may be less than a height of the second conductive pillars 503. A second underfill UF2 may be formed between the second semiconductor chip LC and the second redistribution substrate RDL2.

A mold process may be performed to form a second mold layer MD2 that may cover a top surface of the second redistribution substrate RDL2, the second semiconductor chip LC, and the second conductive pillars 503. In an embodiment, a CMP and/or an etch-back process may be performed to remove at least a portion of the second mold layer MD2 and at least portions of the second conductive pillars 503. This step may expose a top surface of the second semiconductor chip LC, top surfaces of the second conductive pillars 503, and a top surface of the second mold layer MD2. The top surface of the second mold layer MD2 may be coplanar with the top surface of the second semiconductor chip LC and the top surfaces of the second conductive pillars 503.

Referring to FIG. 5E, a third redistribution substrate RDL3 may be formed on the second semiconductor chip LC and the second mold layer MD2. A method that may be substantially similar and/or the same as the method described with reference to FIG. 5A may be employed to form a fifth redistribution dielectric layer IL5, a sixth redistribution dielectric layer IL6, a fifth redistribution pattern RT5, and a sixth redistribution pattern RT6. The fifth redistribution pattern RT5 may be in direct contact with the second conductive pillars 503. At least a portion of the fifth redistribution pattern RT5 may have a linear shape, and/or may not be connected to the second semiconductor chip LC. In an embodiment, the carrier adhesive layer GL and the carrier substrate CR may be removed from the first redistribution substrate RDL1, and external connection members 10 may be bonded to the lower bonding pads BP.

Referring to FIG. 5F, a dicing process using a laser may be performed to remove the first to third redistribution substrates RDL1 to RDL3 and the first and second mold layers MD1 and MD2. Accordingly, a semiconductor package 1000 may be formed as shown in FIG. 1.

FIGS. 5A to 5F illustrate the formation of the semiconductor package 1000 shaped like a chip-last type fan-out wafer level package (FOWLP). However, the present disclosure is not limited thereto, and the semiconductor package 1000 may be shaped like a chip-first type FOWLP. In such an example, the sequence of formation of the first to sixth redistribution dielectric layers IL1 to IL6 may differ from the sequences described with reference to FIGS. 5A to 5F.

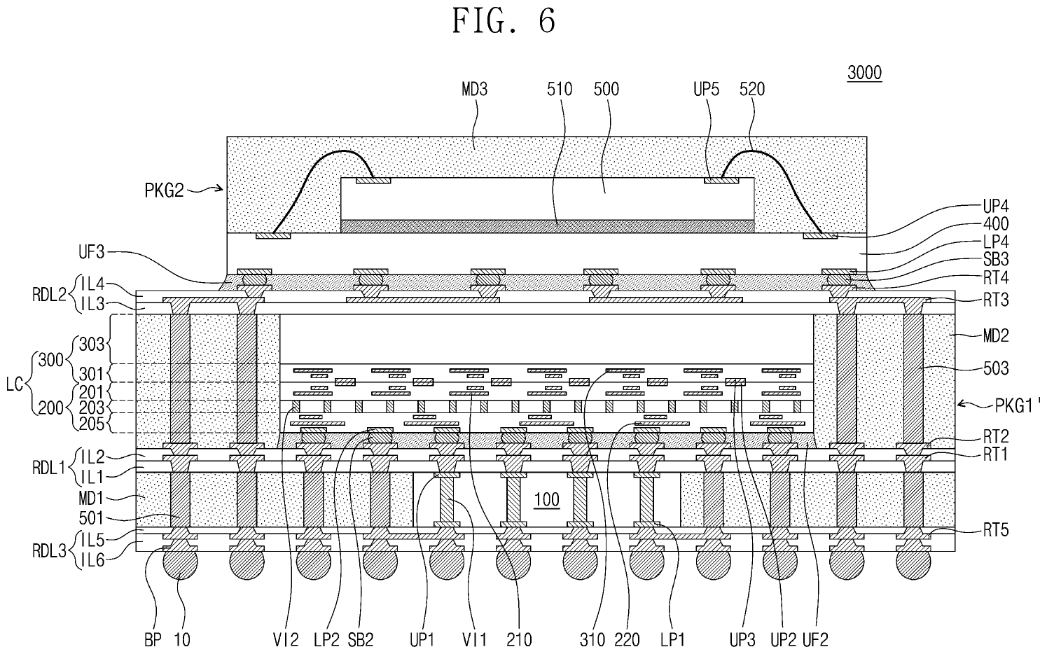

FIG. 6 illustrates a cross-sectional view showing a semiconductor package, according to some embodiments.

Referring to FIG. 6, a semiconductor package 3000 may be shaped like a chip-first type FOWLP. The semiconductor package 3000 may have a structure in which a second sub-package PKG2 is mounted on a first sub-package PKG1′. The first sub-package PKG1′ of FIG. 6 may include and/or may be similar in many respects to the first sub-package PKG1 described above with reference to FIG. 3, and may include additional features not mentioned above. For example, the structure first sub-package PKG1′ may differ from the first sub-package PKG1 of FIG. 3 in that the first inner connection members SB1 may be disposed between the first semiconductor chip 100 and the first redistribution substrate RDL1 and the first underfill UF1 may be interposed between the first semiconductor chip 100 and the first redistribution substrate RDL1. As another example, a bottom surface of the first semiconductor chip 100 may be in contact with the first redistribution substrate RDL1. As another example, the first lower conductive pads LP1 of the first semiconductor chip 100 may be in direct contact with the fifth redistribution pattern RT5. As another example, a bottom surface of the first mold layer MD1 may be coplanar with a bottom surface of the first semiconductor chip 100. The bottom surface of the first mold layer MD1 may be in direct contact with the fifth redistribution dielectric layer IL5. Consequently, repeated descriptions of the first sub-package PKG1′ described above with reference to FIG. 1 may be omitted for the sake of brevity.

The second sub-package PKG2 of FIG. 6 may include and/or may be similar in many respects to the second sub-package PKG2 described above with reference to FIG. 3, and may include additional features not mentioned above. Consequently, repeated descriptions of the second sub-package PKG2 described above with reference to FIG. 3 may be omitted for the sake of brevity.

In a semiconductor package, according to the present disclosure, a semiconductor chip may be wafer-on-wafer bonded to a logic chip including a backside power delivery network layer, and thus it may be possible to provide a chiplet-structured semiconductor package. The logic chip may be provided on its rear surface with a power line in charge of power function. As wafer-on-wafer bonded semiconductor chips have the same size, the semiconductor package may increase in assembly process yield, when compared with related semiconductor packages. As a second redistribution substrate may be provided thereon with a chiplet-structured semiconductor chip whose size and amount of heat are greater than those of a semiconductor chip mounted on a first redistribution substrate, the semiconductor package may improve in thermal radiation performance, when compared with related semiconductor packages.

Although some embodiments of the present disclosure have been discussed with reference to accompanying figures, it is to be understood that various changes in form and details may be made therein without departing from the spirit and scope of the present disclosure. It may be apparent to those skilled in the art that various substitutions, modifications, and changes may be made thereto without departing from the scope and spirit of the present disclosure. It is therefore intended that the appended claims encompass any such modifications and/or embodiments.

What is claimed is:

1. A semiconductor package, comprising:
a first redistribution substrate;
a first semiconductor chip on the first redistribution substrate;
a first mold layer at least partially covering the first redistribution substrate and the first semiconductor chip;
a plurality of first conductive pillars at least partially penetrating the first mold layer and contacting the first redistribution substrate;
a second redistribution substrate on the first mold layer;
a second semiconductor chip on the second redistribution substrate;
a second mold layer at least partially covering the second redistribution substrate and the second semiconductor chip;
a plurality of second conductive pillars at least partially penetrating the second mold layer and contacting the second redistribution substrate; and
a third redistribution substrate on the second mold layer,
wherein the first semiconductor chip comprises a first through via, and
wherein the second semiconductor chip comprises a backside power delivery network layer.

2. The semiconductor package of claim 1, wherein each of the first redistribution substrate, the second redistribution substrate, and the third redistribution substrate comprises:
a plurality of redistribution dielectric layers that are sequentially stacked; and
a plurality of redistribution patterns between the plurality of redistribution dielectric layers.

3. The semiconductor package of claim 1, wherein the first through via comprises a plurality of first through vias,
wherein the first semiconductor chip further comprises:
a plurality of first upper conductive pads on a top surface of the first semiconductor chip; and
a plurality of first lower conductive pads on a bottom surface of the first semiconductor chip,
wherein the plurality of first upper conductive pads and the plurality of first lower conductive pads are respectively coupled with the plurality of first through vias, and
wherein the plurality of first upper conductive pads are coupled with the second redistribution substrate.

4. The semiconductor package of claim 1, further comprising:
a plurality of first inner connection members electrically coupling the first semiconductor chip with the first redistribution substrate.

5. The semiconductor package of claim 1, wherein the second semiconductor chip comprises:
a first semiconductor die comprising the backside power delivery network layer; and
a second semiconductor die comprising an integrated circuit, and
wherein the second semiconductor die is on the first semiconductor die.

6. The semiconductor package of claim 5, wherein the first semiconductor die further comprises a plurality of second upper conductive pads,
wherein the second semiconductor die further comprises a plurality of third upper conductive pads,
wherein the plurality of second upper conductive pads are respectively in contact with the plurality of third upper conductive pads, and
wherein the plurality of second upper conductive pads and the plurality of third upper conductive pads are formed of a same material.

7. The semiconductor package of claim 1, further comprising:
a plurality of second inner connection members electrically coupling the second semiconductor chip with the second redistribution substrate.

8. The semiconductor package of claim 1, wherein the backside power delivery network layer comprises:
a first interlayer dielectric layer; and
a power line in the first interlayer dielectric layer.

9. The semiconductor package of claim 1, wherein the first semiconductor chip has a first width in a first direction,
wherein the second semiconductor chip has a second width in the first direction, and
wherein the second width is greater than the first width.

10. The semiconductor package of claim 1, wherein the plurality of first conductive pillars have a first height,
wherein the plurality of second conductive pillars have a second height, and
wherein the second height is greater than the first height.

11. The semiconductor package of claim 1, wherein the first semiconductor chip has a first thickness,
wherein the second semiconductor chip has a second thickness, and
wherein the second thickness is greater than the first thickness.

12. A semiconductor package, comprising:
a first sub-package; and
a second sub-package on the first sub-package,
wherein the first sub-package comprises:
a first redistribution substrate;
a first semiconductor chip on the first redistribution substrate;
a first mold layer at least partially covering the first redistribution substrate and the first semiconductor chip;
a plurality of first conductive pillars at least partially penetrating the first mold layer and contacting the first redistribution substrate;
a second redistribution substrate on the first mold layer;
a second semiconductor chip on the second redistribution substrate;
a second mold layer at least partially covering the second redistribution substrate and the second semiconductor chip;
a plurality of second conductive pillars at least partially penetrating the second mold layer and contacting the second redistribution substrate; and
a third redistribution substrate on the second mold layer,
wherein the first semiconductor chip comprises a first through via,
wherein the second semiconductor chip comprises a backside power delivery network layer,
wherein the first semiconductor chip has a first width in a first direction,
wherein the second semiconductor chip has a second width in the first direction, and
wherein the second width is greater than the first width.

13. The semiconductor package of claim 12, further comprising:
a plurality of first inner connection members electrically coupling the first semiconductor chip with the first redistribution substrate; and
a plurality of second inner connection members electrically coupling the second semiconductor chip with the second redistribution substrate.

14. The semiconductor package of claim 12, wherein the second sub-package comprises:
a package substrate;
at least one semiconductor die on the package substrate; and
a third mold layer at least partially covering the package substrate and the at least one semiconductor die.

15. The semiconductor package of claim 12, wherein the second semiconductor chip comprises:
a first semiconductor die comprising the backside power delivery network layer; and
a second semiconductor die on the first semiconductor die and comprising an integrated circuit,
wherein the backside power delivery network layer comprises a power line, and
wherein the first semiconductor die comprises:
a first substrate on the backside power delivery network layer;
a frontside wiring layer on the first substrate and comprising a plurality of signal lines; and
a second through via at least partially penetrating the first substrate and coupled with the power line.

16. The semiconductor package of claim 12, wherein each of the first redistribution substrate, the second redistribution substrate, and the third redistribution substrate comprises:
a plurality of redistribution dielectric layers that are sequentially stacked; and
a plurality of redistribution patterns between the plurality of redistribution dielectric layers.

17. A semiconductor package, comprising:
a first redistribution substrate;
a first semiconductor chip on the first redistribution substrate;
a first mold layer at least partially covering the first redistribution substrate and the first semiconductor chip;
a plurality of first conductive pillars at least partially penetrating the first mold layer and contacting the first redistribution substrate;
a second redistribution substrate on the first mold layer;
a second semiconductor chip on the second redistribution substrate;
a second mold layer at least partially covering the second redistribution substrate and the second semiconductor chip;
a plurality of second conductive pillars at least partially penetrating the second mold layer and contacting the second redistribution substrate; and
a third redistribution substrate on the second mold layer,
wherein the first semiconductor chip comprises a first through via,
wherein a bottom surface of the first semiconductor chip is in contact with the first redistribution substrate,
wherein the second semiconductor chip comprises a backside power delivery network layer,
wherein the first semiconductor chip has a first width in a first direction,
wherein the second semiconductor chip has a second width in the first direction, and
wherein the second width is greater than the first width.

18. The semiconductor package of claim 17, wherein each of the first redistribution substrate, the second redistribution substrate, and the third redistribution substrate comprises:
a plurality of redistribution dielectric layers that are sequentially stacked; and
a plurality of redistribution patterns between the plurality of redistribution dielectric layers.

19. The semiconductor package of claim 18, wherein the first semiconductor chip further comprises a plurality of first lower conductive pads on the bottom surface of the first semiconductor chip, and
wherein the plurality of first lower conductive pads are in contact with the plurality of redistribution patterns of the first redistribution substrate.

20. The semiconductor package of claim 18, wherein a bottom surface of the first mold layer is coplanar with the bottom surface of the first semiconductor chip, and
wherein the bottom surface of the first mold layer is in contact with a redistribution dielectric layer of the first redistribution substrate.
